(19) United States
(12) Patent Application Publication
(10) Pub. No.: US 2026/0196171 A1
(43) Pub. Date: Jul. 9, 2026

(54) PIXEL, DISPLAY DEVICE, AND ELECTRONIC DEVICE

(71) Applicant: Samsung Display Co., Ltd., Yongin-Si (KR)

(72) Inventors: Hui Gyeong YUN, Yongin-si (KR); Mi Hae KIM, Yongin-si (KR); Hey Jin SHIN, Yongin-si (KR)

(21) Appl. No.: 19/297,293

(22) Filed: Aug. 12, 2025

(30) Foreign Application Priority Data
Jan. 8, 2025 (KR) 10-2025-0002855

(51) Int. Cl. G09G 3/3233; G09G 3/3266

(52) U.S. Cl. CPC G09G 3/3233; G09G 3/3266; G09G 2300/0819; G09G 2300/0842; G09G 2300/0861; G09G 2310/08; G09G 2320/0257

(57) ABSTRACT

A pixel includes first to seventh transistors. Gate electrodes of the first to seventh transistors are connected to a first node, a third scan line, a first scan line, a second scan line, a first light emission control line, a second emission control line, and a third scan line, respectively. The first to seventh transistors are connected between a second node and a third node, a data line and the first node, a reference power node and the first node, the initialization power node and a fourth node, a first driving power node and the third node, the second node and the fourth node, and the second node and the third node, respectively. A light emitting element is connected to the fourth node. The seventh transistor is turned on in response to a scan signal applied to the third scan line connecting the second node and the third node.

### CROSS-REFERENCE TO RELATED APPLICATION

This application claims priority under 35 U.S.C. § 119(a) to Korean Patent Application No. 10-2025-0002855, filed on Jan. 8, 2025, in the Korean Intellectual Property Office, the disclosure of which is incorporated by reference herein in its entirety.

### BACKGROUND

### 1. Field

The present disclosure relates to a pixel, a display device, and an electronic device.

### 2. Description of the Related Art

The importance of display devices is increasing with the development of multimedia. In lin with this, the use of display devices such as organic light emitting displays (“OLEDs”) and liquid crystal displays (“LCDs”) is increasing.

A display device includes a plurality of pixels. Each of the pixels includes a plurality of transistors, a light emitting element electrically connected to the transistors, and a capacitor. The transistors generate a driving current based on signals provided through the signal lines, and the light emitting element emits light based on the driving current. However, a time point at which data is written may overlap pixels disposed adjacent to each other among a plurality of pixels connected to the same data line. For this reason, a ghost phenomenon in which a pattern displayed on the lower portion of the display panel is displayed as a residual image on the upper portion may occur, and display quality may be deteriorated.

The content set forth above is only intended to help understanding of the background of the technical ideas of the present disclosure and, therefore, it should not be understood as corresponding to prior art known to those skilled in the art to which the present disclosure pertains.

### SUMMARY

Embodiments of the present disclosure provide a pixel, a display device, and an electronic device having improved display quality.

An embodiment of a pixel includes: a first transistor having a gate electrode connected to a first node, the first transistor being connected between a second node and a third node, a second transistor connected between a data line and the first node, and having a gate electrode electrically connected to a third scan line, a third transistor connected between a reference power node and the first node, and having a gate electrode electrically connected to a first scan line, a fourth transistor connected between the initialization power node and a fourth node, and having a gate electrode electrically connected to a second scan line, a fifth transistor connected between a first driving power node, to which a first driving power is supplied, and the third node, and having a gate electrode electrically connected to a first light emission control line, a sixth transistor connected between the second node and the fourth node, and having a gate electrode electrically connected to a second light emission control line, a seventh transistor connected between the second node and the third node, and having a gate electrode electrically connected to the third scan line, and a light emitting element connected to the fourth node. In operation, the seventh transistor is turned on in response to a scan signal applied to the third scan line electrically connecting the second node and the third node to each other.

The pixel may further include a first capacitor connected between the first node and the second node, and a second capacitor connected between the first driving power node and the second node.

The first transistor may further include a back gate electrode connected to one electrode of the second capacitor and the second node.

The light emitting element may be connected between a second driving power node, to which a second driving power is supplied, and the fourth node.

The pixel may further include a first capacitor connected between the first node and the second node, and a second capacitor connected between the reference power node and the second node.

The first transistor may further include a back gate electrode connected to one electrode of the second capacitor and the second node.

The pixel may further include an eighth transistor connected between an electrode of the second capacitor and the reference power node, and having a gate electrode electrically connected to a fourth scan line.

In a first period, the scan signal of the third scan line may be supplied. The first period may include a plurality of horizontal periods.

The first period may include a first sub-period and a second sub-period subsequent to the first sub-period. Each of the first and second sub-periods may include at least one horizontal period.

In the first sub-period, a previous data signal may be applied to a gate electrode of the first transistor through the second transistor. In the second sub-period, a data signal corresponding to the pixel may be applied to the gate electrode of the first transistor through the second sub period.

In the first sub-period, the second node may be electrically connected to the third node through the seventh transistor, such that a voltage level of the second node is substantially the same as the voltage level of the third node.

In the first period, the second and seventh transistors may be turned on, and the third, fifth, and sixth transistors may be turned off.

An embodiment of a display device includes pixels connected to scan lines, light emission control lines, and data lines, and a scan driver for driving the scan lines, where any one of the pixels includes: a first transistor having a gate electrode connected to a first node, the first transistor being connected between a second node and a third node, a second transistor connected between a data line and the first node, and having a gate electrode electrically connected to a third scan line of the scan lines, a third transistor connected between a reference power node and the first node, and having a gate electrode electrically connected to a first scan line of the scan lines, a fourth transistor connected between the initialization power node and a fourth node, and having a gate electrode electrically connected to a second scan line of the scan lines, a fifth transistor connected between a first driving power node, to which a first driving power is supplied, and the third node, and having a gate electrode electrically connected to a first light emission control line of the light emission control lines, a sixth transistor connected between the second node and the fourth node, and having a gate electrode electrically connected to a second light emission control line of the light emission control lines, a seventh transistor connected between the second node and the third node, and having a gate electrode electrically connected to the third scan line and a light emitting element connected to the fourth node. In operation, the seventh transistor is turned on in response to a scan signal applied to the third scan line electrically connecting the second node and the third node to each other.

The display device may further include a first capacitor connected between the first node and the second node, and a second capacitor connected between the first driving power node and the second node.

The display device may further include a first capacitor connected between the first node and the second node, a second capacitor connected between the reference power node and the second node, and an eighth transistor connected between an electrode of the second capacitor and the reference power node, and having a gate electrode electrically connected to a fourth scan line of the scan lines.

In a first period, the scan signal of the third scan line may be supplied. The first period may include a plurality of horizontal periods.

The first period may include a first sub-period and a second sub-period subsequent to the first sub-period. Each of the first and second sub-periods may include at least one horizontal period.

In the first sub-period, a previous data signal may be applied to a gate electrode of the first transistor through the second transistor. In the second sub-period, a data signal corresponding to the pixel may be applied to the gate electrode of the first transistor through the second transistor.

In the first sub-period, the second node may be electrically connected to the third node through the seventh transistor, such that a voltage level of the second node is substantially the same as the voltage level of the third node.

An embodiment of an electronic device includes pixels, and one or more processors configured to control the display device, where any one of the pixels includes: a first transistor having a gate electrode connected to a first node, the first transistor being connected between a second node and a third node, a second transistor connected between a data line and the first node, and having a gate electrode electrically connected to a third scan line, a third transistor connected between a reference power node and the first node, and having a gate electrode electrically connected to a first scan line, a fourth transistor connected between the initialization power node and a fourth node, and having a gate electrode electrically connected to a second scan line, a fifth transistor connected between a first driving power supply node, to which a first driving power is supplied, and the third node, and having a gate electrode electrically connected to a first light emission control line, a sixth transistor connected between the second node and the fourth node, and having a gate electrode electrically connected to a second light emission control line, a seventh transistor connected between the second node and the third node, and having a gate electrode electrically connected to the third scan line and a light emitting element connected to the fourth node. In operation, the seventh transistor is turned on in response to a scan signal applied to the third scan line electrically connecting the second node and the third node to each other.

### BRIEF DESCRIPTION OF THE DRAWINGS

FIG. 1 is a block diagram of a display device according to an embodiment of the present disclosure.

FIG. 2 is a block diagram illustrating an embodiment of a scan driverer and an emission driver, which are shown in the display device of FIG. 1.

FIG. 3 is a circuit diagram illustrating an embodiment of any one of the pixels shown in FIG. 2.

FIG. 4 is a timing diagram illustrating an embodiment of signals supplied to the pixel shown in FIG. 3.

FIG. 5 is a circuit diagram illustrating a pixel according to an embodiment.

FIG. 6 is a circuit diagram illustrating an operation of the pixel of FIG. 3 in the first period of FIG. 4.

FIG. 7 is a block diagram illustrating another embodiment of a scan driverer and an emission driver, which are shown in the display device of FIG. 1.

FIG. 8 is a circuit diagram illustrating another embodiment of any one of the pixels shown i n FIG. 7.

FIG. 9 is a timing diagram illustrating an embodiment of signals supplied to the pixel shown in FIG. 8.

FIG. 10 is a block diagram illustrating an embodiment of an electronic device including the display device of FIG. 1.

FIG. 11 is a diagram illustrating an example where the electronic device of FIG. 10 is a smartphone.

FIG. 12 is a diagram illustrating an example where the electronic device of FIG. 10 is a tablet computer.

### DETAILED DESCRIPTION

Hereinafter, embodiments of the present disclosure will be described in more detail with reference to the accompanying drawings. The embodiments described below provides an understanding of the devices and operation of the devices. In addition, the present disclosure is not limited to the embodiments described herein, but may be embodied in various different forms. Embodiments described herein are provided to thoroughly and completely describe the disclosed contents and to sufficiently transfer the ideas of the disclosure to a person of ordinary skill in the art.

In the specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, or Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, or Z” can be construed as X only, Y only, Z only, or any combination of two or more items X, Y, and Z (e.g., XYZ, XYY, YZ, ZZ). As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

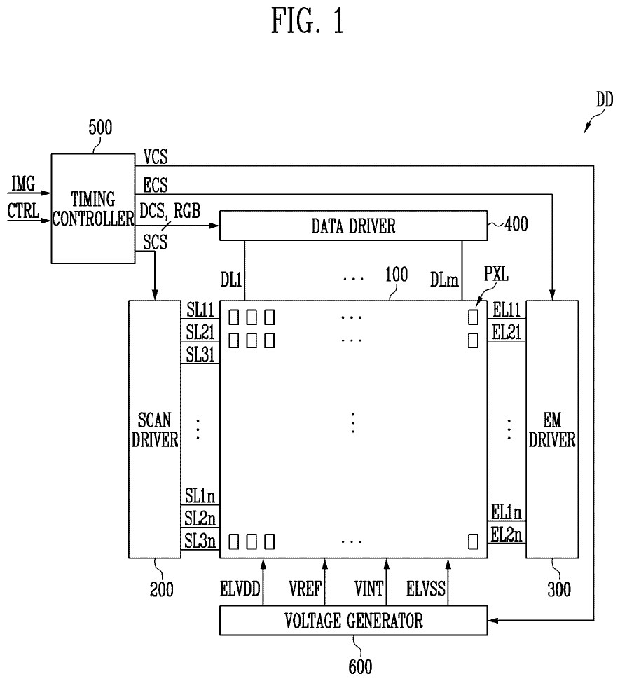

FIG. 1 is a block diagram of a display device according to an embodiment of the present disclosure.

Referring to FIG. 1, a display device DD according to an embodiment of the present disclosure may include a display panel 100, a scan driver 200, an emission driver 300, a data driver 400, and a timing controller 500.

The display panel 100 may include pixels PXL respectively connected to the data lines DL1 to DLm, the scan lines SL11 to SL1n, SL21 to SL2n, SL31 to SL3n, and SL41 to SL4n, and the light emission control lines EL11 to EL1n and EL21 to EL2n. The pixels PXL may be supplied with a first driving power ELVDD, a second driving power ELVSS, an initialization power VINT, and a reference power VREF from the outside.

The pixels PXL may be connected to the scan driver 200 through the scan lines SL11 to SL1n, SL21 to SL2n, SL31 to SL3n, and SL41 to SL4n. The pixels PXL may be connected to the emission driver 300 through the light emission control lines EL11 to EL1n and EL21 to EL2n. The pixels PXL may be connected to the data driver 400 through the data lines DL1 to DLm.

Each of the pixels PXL may include at least one light emitting element configured to generate light. Accordingly, each of the pixels PXL may generate light of a particular color, such as red, green, blue, cyan, magenta, yellow, or the like.

The scan driver 200 may generate a scan signal based on the scan control signal SCS. The scan driver 200 may sequentially provide scan signals to the scan lines SL11 to SL1n, SL21 to SL2n, SL31 to SL3n, and SL41 to SL4n. Here, the scan control signal SCS includes scan start signals, clock signals, and the like, and may be provided from the timing controller 500. For example, the scan driver 200 may include a shift register (or stage) that sequentially generates and outputs a scan signal in a pulse form corresponding to a scan start signal in a pulse shape using clock signals.

The scan driver 200 may be disposed on one side of the display panel 100. However, embodiments are not limited thereto. For example, the scan driver 200 may be divided into two or more drivers that are physically or logically divided, and such drivers may be disposed on one side of the display panel 100 and the other side of the display screen 100 opposite to the one side. As such, the scan driver 200 may be disposed around the display panel 100 in various forms according to embodiments.

The emission driver 300 may generate a light emission control signal based on the emission driving control signal ECS. The emission driver 300 may sequentially or simultaneously provide light emission control signals to the light emission control lines EL11 to EL1n and EL21 to EL2n. Here, the emission driving control signal ECS includes a light emission start signal, light emission clock signals, and the like, and may be provided from the timing controller 500. For example, the emission driver 300 may include a shift register that sequentially generates and outputs a light emission control signal in a pulse form corresponding to a light emission start signal in a pulse shape using light emission clock signals.

The data driver 400 may receive the data control signal DCS and the image data RGB from the timing controller 500. The data driver 400 may supply data signals to the data lines DL1 to DLm in response to the data control signal DCS. For example, the data driver 400 may generate an analog data signal using the digital image data RGB and supply the generated data signal to the data lines DL1 to DLm to be synchronized with the scan signal.

The timing controller 500 may control various operations of the display device DD. The timing controller 500 may receive the input image data IMG and a control signal CTRL for controlling display thereof from the outside. The timing controller 500 may generate the scan control signal SCS, the emission driving control signal ECS, the data control signal DCS, and the voltage control signal VCS in response to the control signal CTRL. In addition, the timing controller 500 may rearrange the input image data IMG into the digital image data RGB and supply the digital image data RGB to the data driver 400.

In embodiments, the display device DD may further include a voltage generator 600 for supplying a voltage of the first driving power ELVDD, a voltage of the second driving power ELVSS, a voltage of an initialization power VINT, and a voltage of a reference power VREF to the display panel 100.

The voltage generator 600 may operate in response to the voltage control signal VCS supplied from the timing controller 500. For example, the voltage generator 600 may be configured to generate a plurality of voltages by receiving an input voltage from outside the display device DD, adjusting the received voltage, and regulating the adjusted voltage.

The first driving power ELVDD and the second driving power ELVSS may be used to drive the light emitting element. To this end, the voltage of the first driving power ELVDD may be set to a higher level than the voltage of the second driving power ELVSS. For example, the first driving power ELVDD may be a positive voltage and the second driving power ELVSS may be a negative voltage.

The initialization power VINT may be a power for initializing the pixels PXL. For example, a driving transistor included in the pixels PXL may be initialized by a voltage of the initialization power VINT. The initialization power VINT may be set to a voltage lower than the data signal.

The reference power VREF may be a power for initializing the pixels PXL. For example, a capacitor or a transistor included in the pixels PXL may be initialized by a voltage of the reference power VREF. The reference power VREF may be a positive voltage. For example, the reference power VREF may have the same voltage level as the first driving power ELVDD, but embodiments are not limited thereto.

Two or more components of the data driver 400, the timing controller 500, and the voltage generator 600 may be mounted on one integrated circuit. For example, the data driver 400, the timing controller 500, and the voltage generator 600 may be included in a driver integrated circuit (DIC). In this case, the data driver 400, the timing controller 500, and the voltage generator 600 may be functionally separate components in one driver integrated circuit (DIC). In other embodiments, at least one of the data driver 400, the timing controller 500, and the voltage generator 600 may be provided as a component separate from the driver integrated circuit (DIC).

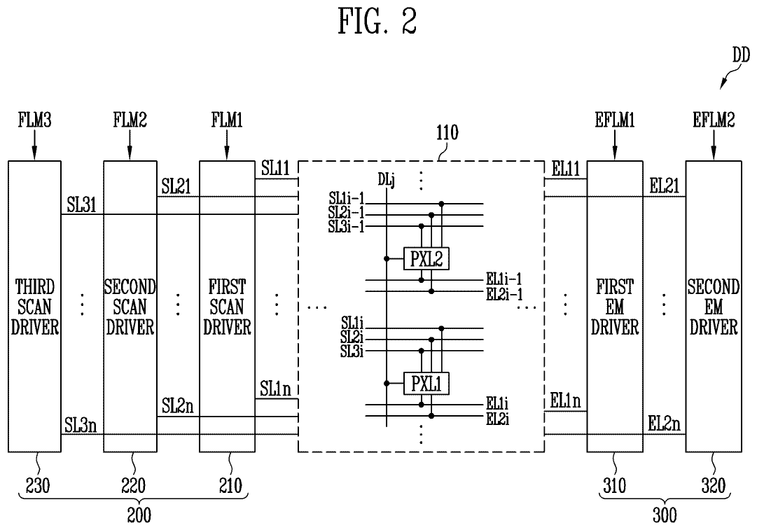

FIG. 2 is a block diagram illustrating an embodiment of a scan driverer and an emission driver, which are shown in the display device of FIG. 1.

Referring to FIGS. 1 and 2, the scan driver 200 may include a first scan driver 210, a second scan driver 220, and a third scan driver 230.

In embodiments, the first pixel PXL1 disposed in the i-th (i is a natural number greater than 1) row and the j-th (j is a natural number) column may be connected with the scan lines SL1i, SL2i, and SL3i corresponding to the i-th pixel row, the light emission control lines EL1i and EL2i corresponding to the i-th pixel row and the data line DLj corresponding to the j-th pixel column. The second pixels PXL2 disposed in the i-1th row and the j-th column may be connected to the scan lines SL1i-1, SL2i-1, and SL3i-1 corresponding to the i-1th pixel row, the light emission control lines EL1i-1 and EL2i-1 corresponding to i-1th pixel column, and the data line DLj corresponding to the j-th pixel column. However, embodiments are not limited thereto. For example, signal lines connected to the pixels PXL may be variously set corresponding to the circuit structure of the pixels PXL.

The scan driver 200 may receive the scan control signal SCS from the timing controller 500, and supply the first scan signal, the second scan signal, and the third scan signal to the first scan lines S11 to S1n, the second scan lines S21 to S2n, and the third scan lines S31 to S3n, respectively, based on the scan control signal SCS.

The first to third scan signals may be set to a gate-on voltage corresponding to the type of transistor to which the scan signals are applied. The transistor receiving the scan signal may be set to a turn-on state when the scan signal is applied. For example, the gate-on voltage of the scan signal applied to the N-type transistor may be a logic high level, and the gate-on pressure of the scan signal used for the P-type transistor may also be a logic low level. Hereinafter, the meaning of “a scan signal is applied” may be understood as that the scan signal is applied at a logic level that turns on the transistor controlled thereby.

The scan control signal SCS may include first to third scan start signals FLM1 to FLM3. The first to third scan start signals FLM1 to FLM3 may be applied to the first to third scan drivers 210 to 230, respectively.

The width, application timing, and the like of the first to third scan start signals FLM1 to FLM3 may be determined according to driving conditions and frame frequencies of the pixels PXL. The first to third scan signals may be applied based on the first to third scan start signals FLM1 to FLM3, respectively. For example, the application timing of at least one of the first to third scan signals may be different from the application timings of the remaining signals.

The first scan driver 210 may sequentially apply the first scan signal to the first scan lines S11 to S1n in response to the first scan start signal FLM1. The second scan driver 220 may sequentially apply the second scan signal to the second scan lines S21 to S2n in response to the second scan start signal FLM2. The third scan driver 230 may sequentially apply the third scan signal to the third scan lines S31 to S3n in response to the third scan start signal FLM3.

FIG. 2 illustrates, but is not limited to, a first scan driver 210, a second scan driver 220, and a third scan driver 230 to be connected to first scan lines SL11 to SL1n, second scan lines SL21 to SL2n, and third scan lines SL31 to SL3n, respectively. For example, at least two of the first scan lines SL11 to SL1n, the second scan lines SL21 to SL2n, and the third scan lines SL31 to SL3n may be driven by one scan driver.

The emission driver 300 may include a first emission driver 310 and a second emission driver 320.

The emission driving control signal ECS may include first and second light emission start signals EFLM1 and EFLM2. The first and second light emission start signals EFLM1 and EFLM2 may be applied to the first and second emission drivers 310 and 320, respectively.

The width, application timing, and the like of the first and second light emission start signals EFLM1 and EFLM2 may be determined according to driving conditions and frame frequencies of the pixels PXL. The first and second light emission control signals may be applied based on the first and second emission start signals EFLM1 and EFLM2, respectively. For example, the application timing of the first light emission control signal may be different from that of the second light emission control signal.

The first emission driver 310 may sequentially apply the first light emission control signal to the first light emission control lines EL11 to EL1n in response to the first emission start signal EFLM1. The second emission driver 320 may sequentially apply the second light emission control signal to the second light emission control lines EL21 to EL2n in response to the second light emission start signal EFLM2.

FIG. 2 shows first and second emission drives 310, 320 to be connected to first and second light emission control lines EL11 to EL1n, EL21 to EL2n, respectively, but is not limited thereto. For example, the first and second light emission control lines EL11 to EL1n and EL21 to EL2n may be driven by one light emission driver.

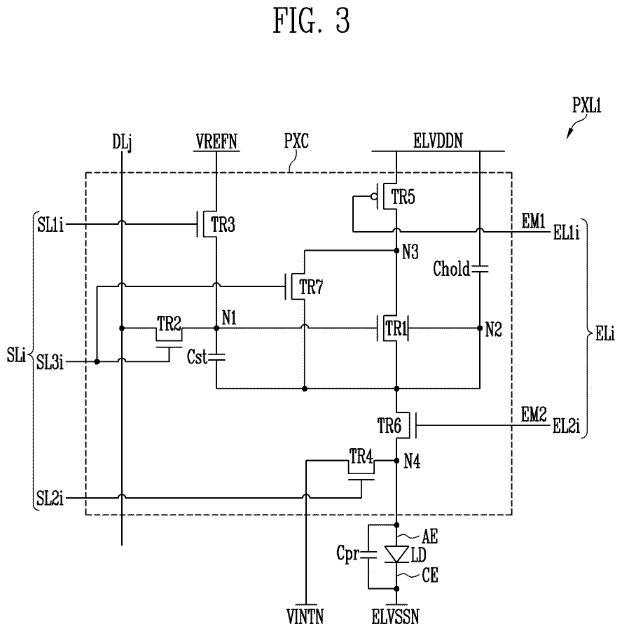

FIG. 3 is a circuit diagram illustrating an embodiment of any one of the pixels shown in FIG. 2.

Referring to FIG. 3, the first pixel PXL1 may include a pixel circuit PXC and a light emitting element LD. The first pixel PXL1 may further include a parasitic capacitor Cpr between the anode electrode AE and the cathode electrode CE of the light emitting element LD. Although the first pixel PXL1 is described as an example in FIG. 3, the remaining pixels may be configured in the same manner as the first pixel PXL1.

The pixel circuit PXC may be connected to a scan line SLi corresponding to an i-th pixel row among the scan lines SL11 to SL1n, SL21 to SL2n, SL31 to SL3n, and SL41 to SL4n of FIG. 1, a light emission control line ELi corresponding to an i-th pixel row among light emission control lines EL11 to EL1n and EL21 to EL2n of FIG. 1 and a data line DLj corresponding to a j-th pixel column among the data lines DL1 to DLm of FIG. 1. The pixel circuit PXC is configured to control the light emitting element LD according to signals received through these signal lines.

In embodiments, the scan line SLi corresponding to the i-th pixel row may include one or more sub scan lines. For example, the scan line SLi corresponding to the i-th pixel row may include first to third sub scan lines SL1i, SL2i, and SL3i. The light emission control line ELi corresponding to the i-th pixel row may include one or more sub-emission control lines. For example, the i-th light emission control line ELi may include first and second sub light emission control lines EL1i, EL2i.

The pixel circuit PXC may include first to seventh transistors TR1 to TR7.

In embodiments, at least one of the first to seventh transistors TR1 to TR7 may be low-temperature poly-silicon (LTPS) transistors. As shown in FIG. 3, the fifth transistor TR5 may be a P-type low temperature polycrystalline silicon transistor, and the remaining transistors TR1 to TR4 and TR6 to TR7 may be N-type low temperature multicrystalline silicon transistors. However, embodiments are not limited thereto. For example, the first to seventh transistors TR1 to TR7 may all be P-type low-temperature polycrystalline silicon transistors. For another example, at least one of the first to seventh transistors TR1 to TR7 may be oxide semiconductor transistors.

The first transistor TR1 may be connected between the second node N2 and the third node N3. The gate electrode of the first transistor TR1 is connected to the first node N1, so that the first transistor TR2 may be turned on according to the voltage level of the first node N1. The first transistor TR1 may further include one electrode of the second capacitor Chold and a back gate electrode connected to the second node N2. The first transistor TR1 may be referred to as a driving transistor.

The second transistor TR2 may be connected between the j-th data line DLj and the first node N1. The gate electrode of the second transistor TR2 is connected to the third sub scan line SL3i, so that the second transistor TR2 may be turned on in response to the scan signal of the third sub scan line SL3i.

The third transistor TR3 may be connected between the reference power node VREFN to which the reference power is supplied and the first node N1. The gate electrode of the third transistor TR3 is connected to the first sub scan line SL1i, so that the third transistor TR3 may be turned on in response to the scan signal of the first sub scan line SL1i.

The fourth transistor TR4 may be connected between the initialization power node VINTN to which the initialization power is supplied and the fourth node N4. The fourth node N4 may be a node connected to the anode electrode AE of the light emitting element LD. The initialization power node VINTN may be configured to deliver a voltage of the initialization power. In embodiments, initialization power may be provided by voltage generator 600 of FIG. 1. In other embodiments, the initialization power may be provided by an external device. The gate electrode of the fourth transistor TR4 is connected to the second sub scan line SL2i, so that the fourth transistor TR4 may be turned on in response to the scan signal of the second sub scan line SL2i.

The fifth transistor TR5 may be connected between the first driving power node ELVDDN and the third node N3. The third node N3 may be a node connected to one electrode (e.g., a drain electrode) of the first transistor TR1 and one electrode (e, g., a drain electrode) of the seventh transistor TR7. The gate electrode of the fifth transistor TR5 is connected to the first sub light emission control line EL1i, so that the fifth transistor TR5 may be turned on in response to the light emission control signal of the first sub light emission control line EL1i.

The sixth transistor TR6 may be connected between the second node N2 and the fourth node N4. The second node N2 may be a node connected to another electrode (e.g., a source electrode) of the first transistor TR1 and another electrode (e, g., a source electrode) of the seventh transistor TR7. The gate electrode of the sixth transistor TR6 is connected to the second sub light emission control line EL2i, so that the sixth transistor TR6 may be turned on in response to the light emission control signal of the second sub-light emission control line EL2i.

The seventh transistor TR7 may be connected between the second node N2 and the third node N3. The gate electrode of the seventh transistor TR7 is connected to the third sub scan line SL3i, so that the seventh transistor TR7 may be turned on in response to the scan signal of the third sub scan line SL3i. As the seventh transistor TR7 is turned on, the second node N2 and the third node N3 may have the same voltage level in response to the scan signal of the third sub scan line SL3i.

The pixel circuit PXC may include a first capacitor Cst and a second capacitor Chold.

The first capacitor Cst may be connected between the first node N1 and the second node N2. The first capacitor Cst may store a difference voltage between the first node N1 and the second node N2. For example, the first capacitor Cst may store a data signal and a voltage corresponding to a threshold voltage of the first transistor TR1.

The second capacitor Chold may be connected between the first driving power node ELVDDN and the second node N2. One electrode of the second capacitor Chold may be connected to the back gate electrode of the first transistor TR1. The second capacitor Chold may have a higher storage capacity than the first capacitor Cst. For example, since the second capacitor Chold has a higher storage capacity than the first capacitor Cst, the second capacitor Chold may reduce or minimize a voltage change of the second node N2 in response to the voltage change of the first node N1.

The light emitting element LD may include an anode electrode AE, a cathode electrode CE, and a light emitting layer. The light emitting layer may be disposed between the anode electrode AE and the cathode electrode CE. After the data signal transmitted through the j-th data line DLj is reflected in the voltage of the first node N1, the fifth and sixth transistors TR5 and TR6 may be turned on when the light emission control signal of the first sub light emission control line EL1i is enabled to a low level and the light emission control signals of the second sub light emission control lines EL2i are enabled to a high level. In addition, the first transistor TR1 may be turned on according to the voltage of the first node N1, and thus a current may flow from the first driving power node ELVDDN to the second driving power node ELVSSN. The light emitting element LD may emit light according to the amount of flowing current.

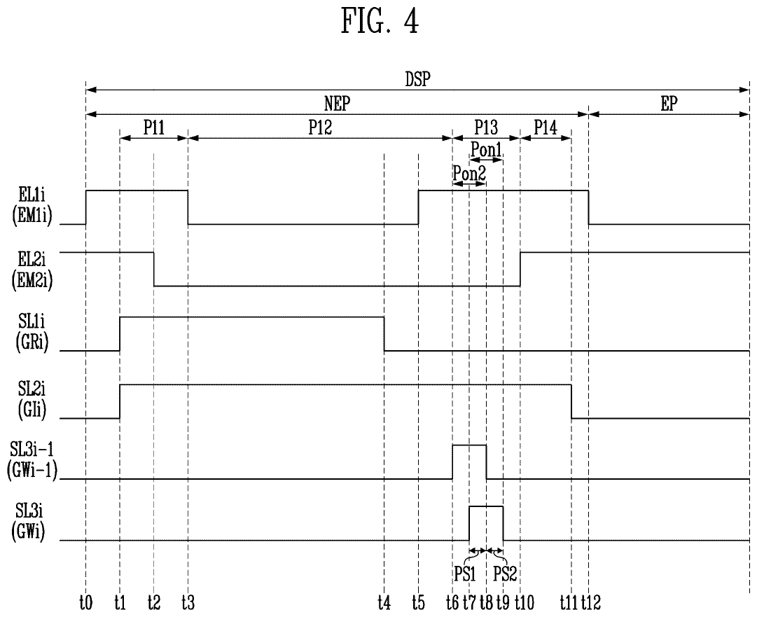

FIG. 4 is a timing diagram illustrating an embodiment of signals supplied to the pixel shown in FIG. 3. FIG. 4 illustrates a timing diagram in a case where a fifth transistor TR5 among the first to seventh transistors TR1 to TR7 is a P-type transistor as an example, but embodiments are not limited thereto.

Further, in FIG. 4, for convenience of description, examples of the first and second light emission control signals EM1i and EM2i and the first to third scan signals GRi, GIi and GWi that control timing of the first pixels PXL1 (see FIG. 2) are illustrated. Specifically, the first and second light emission control signals EM1i, EM2i, and the first to third scan signals GRi, GIi, and GWi are shown as signals provided to the first pixel PXL1 in the i-th pixel row among pixels connected to the j-th data line DLj. However, the 3-1th scan signal GWi-1 is illustrated as a signal provided to the second pixel PXL2 in the i-1th pixel row among pixels connected to the j-th data line DLj.

In the display panel 100 of FIG. 1, pixels PXL disposed on the same horizontal line may be simultaneously driven, and pixels PXL arranged on different horizontal lines may be sequentially driven corresponding to respective horizontal periods.

The display scan period DSP may include a non-emission period NEP and an emission period EP. The emission period EP may be a period in which the first light emission control signal EM1i applied to the first sub emission control line EL1i has a logic low level and the second light emission control signal EM2i applied to the second sub emission controls line EL2i has a logic high level. The non-emission period NEP may be a period other than the emission period EP.

In an embodiment, in a non-emission period NEP, any one of the fifth and sixth transistors TR5, TR6 may be in a turn-off state. The non-emission period NEP may be defined by the first and second emission control signals EM1i, EM2i. For example, at a zeroth time point t0, the first light emission control signal EM1i may transition from a logic low level to a logic high level, and the non-light emission period NEP may begin. At a second time point t2, the second light emission control signal EM2i may transition from a logic high level to a logic low level, and at a third time point t3, the first light emission control signal EM1i may transition from the logic high level to the logic low level. As such, in the non-emission period NEP, a period in which the first light emission control signal EM1i has a logic low level and a period in which a second light emission control signal EM2i has a logic high level may not overlap.

The non-emission period NEP may include an initialization period P11. In the initialization period P11, an initialization operation of the pixels PXL may be performed.

The first scan signal GRi applied to the first sub scan line SL1i at the first time point t1 may transition from a logic low level to a logic high level. A logic high level first scan signal GRi may be provided to the gate electrode of the third transistor TR3 at the first time point t1. As the third transistor TR3 is turned on in response to the first scan signal GRi, a voltage of the reference power node VREFN may be provided to the first node N1. Accordingly, a voltage of the first node N1 (e.g., a voltage of a gate electrode of the first transistor TR1) may be initialized to a voltage of the reference power node VREFN.

The second scan signal GIi applied to the second sub scan line SL2i at the first time point t1 may transition from a logic low level to a logic high level. A logic high level second scan signal GIi may be provided to the gate electrode of the fourth transistor TR4 at the first time point t1. As the fourth transistor TR4 is turned on in response to the second scan signal GIi, a voltage of the initialization power node VINTN may be provided to the fourth node N4. Accordingly, a voltage of the fourth node N4 (e.g., a voltage of an anode electrode of the light emitting element LD) may be initialized to a voltage of the initialization power node VINTN.

In FIG. 4, the time point at which the voltage of the reference power node VREFN is provided to the first node N1 is shown to be the same as the time point when the voltage of the initialization power node VINTN is supplied to the fourth node N4, but the present disclosure is not limited thereto. For example, a time point at which the voltage of the reference power node VREFN is provided to the first node N1 and a time point at which a voltage of the initialization power node VINTN is supplied to the fourth node N4 may be different from each other.

In particular, at the second time point t2, the second light emission control signal EM2i applied to the second sub emission control line EL2i may transition from a logic high level to a logic low level. For example, a logic high level second light emission control signal EM2i may be provided to the gate electrode of the sixth transistor TR6 until the second time point t2. The sixth transistor TR6 may be turned on in response to the second light emission control signal EM2i while the fourth transistor TR4 is turned on from the first time point t1 to the second time point t2. Then, after the second time point t2, the sixth transistor TR6 may be turned off in response to the second light emission control signal EM2i. Accordingly, the voltage of the initialization power node VINTN may be provided to the second node N2 from the first time point t1 to the second time point t2. The voltage of the second node N2 (e.g., the voltage of the source electrode of the first transistor TR1) may be initialized to the voltage of the initialization power node VINTN.

The non-emission period NEP may include a threshold voltage compensation period P12. In the threshold voltage compensation period P12, an operation of compensating for the threshold voltage of the first transistor TR1 may be performed.

From the first time point t1 to the fourth time point t4, the first scan signal GRi may be maintained at a logic high level. As the third transistor TR3 is turned on, a voltage of the reference power node VREFN may be provided to the first node N1.

In the threshold voltage compensation period P12, the sixth transistor TR6 may be in a turn-off state. Regardless of the voltage of the initialization power node VINTN that initializes the anode of the light emitting element LD, threshold voltage compensation may be performed according to the voltage of the second node N2. For example, from the third time point t3 to the fourth time point t4, the voltage of the first node N1 may be maintained at a voltage of the reference power node VREFN, and the voltage of the second node N2 may be maintained at the voltage obtained by subtracting the threshold voltage of the first transistor TR1 from the voltage of the reference Power Node VREFN. Accordingly, a threshold voltage of the first transistor TR1 corresponding to a difference between the voltage of the first node N1 and the voltage of the second node N2 may be stored in the first capacitor Cst.

At a third time point t3, the first light emission control signal EM1i may transition from a logic high level to a logic low level. Accordingly, the fifth transistor TR5 may be turned on in response to the first light emission control signal EM1i, and a voltage of the first driving power node ELVDDN may be provided to the third node N3 (e.g., a drain electrode of the first transistor TR1).

Thereafter, at the fifth time point t5, the first light emission control signal EM1i may transition from the logic low level to the logic high level. Accordingly, the fifth transistor TR5 may be turned off.

The non-emission period NEP may include a data write period P13. In the data writing period P13, a data writing operation of the pixels PXL may be performed. For example, in the data writing period P13, a voltage corresponding to a previous data signal may be stored in the second pixel PXL2, and a voltage corresponding to the current data signal may be saved in the first pixel PXL1.

Referring to FIGS. 2, 3, and 4, during the first period Pon1, the third scan signal GWi may be applied to the third sub scan line SL3i of the first pixel PXL1 disposed in the i-th pixel row and the j-th pixel column. During the second period Pon2, the 3-1th scan signal GWi-1 may be applied to the 3-1th sub scan line SL3i-1 of the second pixel PXL2 disposed in the i-1th pixel row and the j-th pixel column. The first and second periods Pon1 and Pon2 may partially overlap.

The third scan signal GWi applied to the third sub scan line SL3i of the first pixel PXL1 at the seventh time point t7 may transition from a logic low level to a logic high level. A logic high level third scan signal GWi may be provided to the gate electrode of the second transistor TR2 of the first pixel PXL1 at the seventh time point t7. As the second transistor TR2 is turned on in response to the third scan signal GWi, a data signal may be applied to the first node N1. Thereafter, at the ninth time point t9, the third scan signal GWi may transition from the logic high level to the logic low level. Accordingly, during the first period Pon1 from the seventh time point t7 to the ninth time point t9, the third scan signal GWi is provided to the third sub scan line SL3i of the first pixel PXL1, and the second transistor TR2 of the first pixel (PXL1) may be turned on.

At a sixth time point t6 prior to the seventh time point t7, the 3-1th scan signal GWi-1 applied to the 3-1th sub scan line SL3i-1 of the second pixel PXL2 may transition from a logic low level to a logic high level. A logic high level 3-1th scan signal GWi-1 may be provided to the gate electrode of the second transistor TR2 of the second pixel PXL2 at the sixth time point t6. As the second transistor TR2 is turned on in response to the 3-1th scan signal GWi-1, a data signal may be applied to the first node N1. Thereafter, at the eighth time point t8, the 3-1th scan signal GWi-1 may transition from a logic high level to a logic low level. Accordingly, during the second period Pon2 from the sixth time point t6 to the eighth time point t8, the 3-1th scan signal GWi-1 is provided to the 3-1th sub scan line SL3i-1 of the second pixel PXL2, and the second transistor TR2 of the second pixels PXL2 may be turned on.

Each of the first and second periods Pon1 and Pon2 may include a plurality of horizontal periods. Here, the horizontal period may mean a time period in which data signals are applied to the pixels PXL of each row. Accordingly, the previous data signal and the current data signal may be sequentially provided to the first node N1 of each of the second and first pixels PXL2 and PXL1. For example, the first period Pon1 during which the third scan signal GWi is applied may include at least two horizontal periods. In this case, the first period Pon1 may include a first sub-period PS1 and a second sub-period PS2 after the first sub-period PS1, respectively. Each of the first and second sub-periods PS1 and PS2 may include at least one horizontal period. The first sub-period PS1 is a period in which the 3-1th scan signal GWi-1 and the third scan signal GWi have a gate-on voltage at the same time, and may be a period from the seventh time point t7 to the eighth time point t8. The second sub-period PS2 may be a period from the eighth time point t8 to the ninth time point t9 in which the 3-1th scan signal GWi-1 has a gate-off voltage and the third scan signal GWi has a gate-on voltage.

According to an embodiment, in the first sub-period PS 1, the 3-1th scan signal GWi-1 and the third scan signal GWi may overlap each other. For example, in the first sub-period PS1, a time at which a data voltage is applied to the first pixel PXL1 among pixels connected to the j-th data line DLj and a time at which the data voltage is apply to the second pixel PXL2 may overlap each other.

In the first sub-period PS1, a voltage corresponding to the previous data signal may be applied to the gate electrode of the first transistor TR1 included in the first pixel PXL1. Accordingly, a microcurrent may flow from the drain electrode of the first transistor TR1 of the first pixel PXL1 to the source electrode, and the voltage of the second node N2 may be changed. As the voltage of the second node N2 changes, voltages stored in the first capacitor Cst and the second capacitor Chold may change. Accordingly, the threshold voltage of the first transistor TR1 of the first pixel PXL1 may be compensated with an unintended voltage. As such, a ghost phenomenon may be visually recognized due to a difference in the threshold voltage compensation amount of the first transistors generated according to the previous data signal in the adjacent first and second pixels PXL1 and PXL2.

In view of these points, a seventh transistor TR7 may be connected between the second node N2 and the third node N3. In the first sub-period PS1, the seventh transistor TR7 of the second pixel PXL2 may be turned on in response to the 3-1th scan signal GWi-1, and the seventh transistor TR7 of the first pixel circuit PXL1 may be turned on, in response to the third scan signal GWi.

The second node N2 may have the same voltage level as the third node N3 by the seventh transistor TR7. Accordingly, even if a voltage corresponding to the previous data signal is applied to the gate electrode of the first transistor TR1, the voltage of the second node N2 may be maintained. Accordingly, it is possible to prevent the voltage of the second node N2 from being unintentionally changed by the previous data signal in the first sub-period PS1.

The non-emission period NEP may include an anode initialization period P14. In the anode initialization period P14, an operation of initializing the voltage of the anode electrode AE of the light emitting element LD may be performed.

The second light emission control signal EM2i applied to the second sub light emission control line EL2i at the tenth time point t10 may transition from a logic low level to a logic high level. For example, a logic high level second light emission control signal EM2i may be provided to the gate electrode of the sixth transistor TR6 from the tenth time point t10.

Thereafter, the second scan signal GIi applied to the second sub scan line SL2i at the eleventh time point t11 may transition from a logic high level to a logic low level. A logic high level second scan signal GIi may be provided to the gate electrode of the fourth transistor TR4 until the eleventh time point t11.

From the tenth time point t10 to the eleventh time point t11, the sixth transistor TR6 may be turned on in response to the second light emission control signal EM2i, and the fourth transistor TR4 may be turned on responsive to the second scan signal GIi. Accordingly, the voltage of the initialization power node VINTN may be provided to the anode electrode AE and the second node N2 of the light emitting element LD.

Finally, the non-emission period NEP may end and the emission period EP may begin at the twelfth time point t12. A light emission operation of the pixels PXL may be performed in the emission period EP. The first light emission control signal EM1i applied to the first sub light emission control line EL1i at the twelfth time point t12 may transition from a logic high level to a logic low level. The fifth and sixth transistors TR5 and TR6 may be turned on from the twelfth time point t12. Accordingly, during the emission period EP, a driving current corresponding to a voltage stored in the first capacitor Cst based on the data signal written in the data writing period P13 may be provided to the light emitting element LD by the first transistor TR1. The light emitting element LD may emit light based on a driving current.

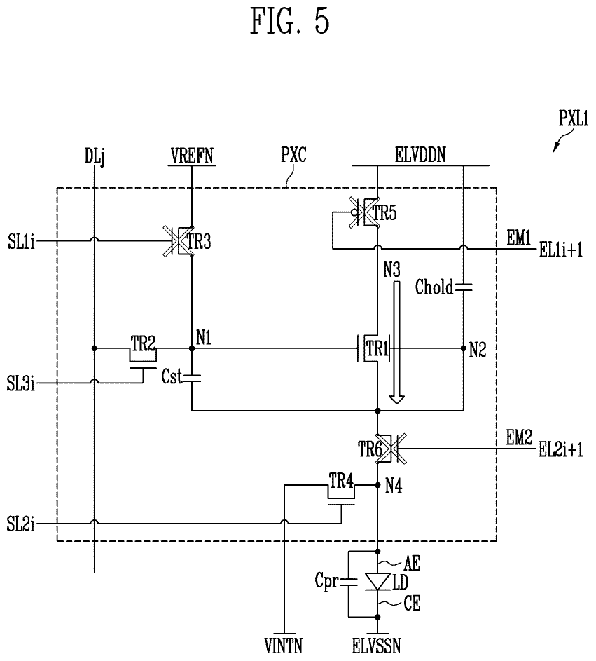

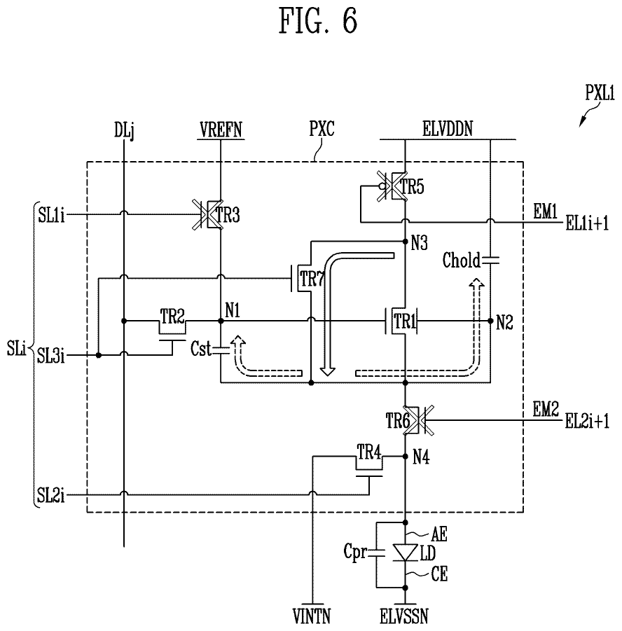

FIG. 5 is a circuit diagram illustrating a pixel according to an embodiment. FIG. 6 is a circuit diagram illustrating an operation of the pixel of FIG. 3 in the first period of FIG. 4.

Referring to FIGS. 4, 5, and 6, in the first period Pon1, third, fifth, and sixth transistors TR3, TR5, and TR6 of the first pixel PXL1 may be turned off, and first, second, fourth, and seventh transistors TR1, TR2, TR4, and TR7 may be turned on.

The first period Pon1 may include a first sub-period PS1 in which a voltage corresponding to a previous data signal (or a previous data voltage) is applied to the first node N1, and a second sub-period PS2 in which a voltage (or a current data voltage) corresponding to a current data signal is applied to the second node N1.

FIG. 5 illustrates an example in which the seventh transistor TR7 is not connected between the second node N2 and the third node N3.

In the first sub-period PS1, a previous data voltage may be applied to the gate electrode (or the first node N1) of the first transistor TR1 included in the first pixel PXL1. Accordingly, a microcurrent may flow from the drain electrode (or the third node N3) of the first transistor TR1 of the first pixel PXL1 to the source electrode (or the second node N2), and the voltage of the second node N2 may be changed. As the voltage of the second node N2 changes, the ratio of the amount of charge stored in the first capacitor Cst and the second capacitor Chold may change, and the voltages stored therein may also change. This may further generate a luminance difference corresponding to a change in capacitances of the first capacitor Cst and the second capacitor Chold due to the previous data voltage when the current data voltage is applied to the second sub-period PS2.

FIG. 6 illustrates an example in which the seventh transistor TR7 is connected between the second node N2 and the third node N3.

A seventh transistor TR7 that is turned on in response to the third scan signal GWi may be connected between the second node N2 and the third node N3. The second node N2 and the third node N3 may have the same voltage level as the second and seventh transistors TR2, TR7 are turned on in response to the third scan signal GWi of the third sub scan line SL3i. For example, as the second transistor TR2 is maintained in the turn-on state, the first node N1 may change from the voltage of the reference power node VREFN to the previous data voltage in the first sub-period PS1. In this case, the seventh transistor TR7 may also be maintained in a turn-on state together with the second transistor TR2. Accordingly, even if the previous data voltage is applied to the first node N1, a microcurrent may not flow from the drain electrode of the first transistor TR1 to the source electrode. Even if the previous data voltage is applied to the first node N1, the ratio of the amount of charge stored in the first capacitor Cst and the second capacitor Chold may be maintained, and the voltages stored therein may also be maintained. That is, the voltage of the second node N2 may be kept constant without being greatly affected by the previous data voltage of the first node N1.

Accordingly, when the current data voltage is applied to the gate electrode of the first transistor TR1 included in the first pixel PXL1 in the second sub-period PS2, data writing may proceed in a state in which the voltage of one electrode (for example, the second node N2) of the first capacitor Cst is fixed. The current data voltage may be distributed according to the capacitance ratio of the first capacitor Cst and the second capacitor Chold regardless of the previous data voltage.

For example, in the second sub-period PS2, the first node N1 may change from the voltage of the reference power node VREFN to the current data voltage. The voltage of the second node N2 may be changed to correspond to the voltage change amount of the first node N1 according to the coupling of the first capacitor Cst. Specifically, the voltage of the second node N2 may be changed based on a product of a value obtained by subtracting the voltage of the reference power node VREFN from the current data voltage and a proportionality constant. The voltage of the second node N2 may be calculated by summing a value obtained by multiplying a value obtained by subtracting the voltage of the reference power node VREFN from the data voltage by a proportional constant and a value obtained by deducting the threshold voltage of the first transistor TR1 from the voltage of the base power node VREFN. Here, the proportionality constant may be a ratio obtained by dividing the charge amount stored in the first capacitor Cst by the total charge amounts obtained by summing the charge amounts stored in the first and second capacitors Cst and Chold. The amount of charge stored in the first capacitor Cst may be calculated by multiplying the difference between the voltage of the first node N1 and the voltage of the second node N2 by the capacitance of the first capacitor Cst. The amount of charge stored in the second capacitor Chold may be calculated by multiplying the difference between the voltage of the first driving power node ELVDDN and the voltage of the second node N2 by the capacitance of the second capacitor Chold.

In this way, by connecting the seventh transistor TR7 that operates to be turned on in response to the third scan signal GWi between the second node N2 and the third node N3, the voltage levels of the source electrode and the drain electrode of the first transistor TR1 may be kept the same for the first period Pon1. Accordingly, by compensating the threshold voltage of the first transistor TR1 regardless of the previous data voltage, it is possible to improve the ghost phenomenon occurring in a specific pattern and improve the display quality.

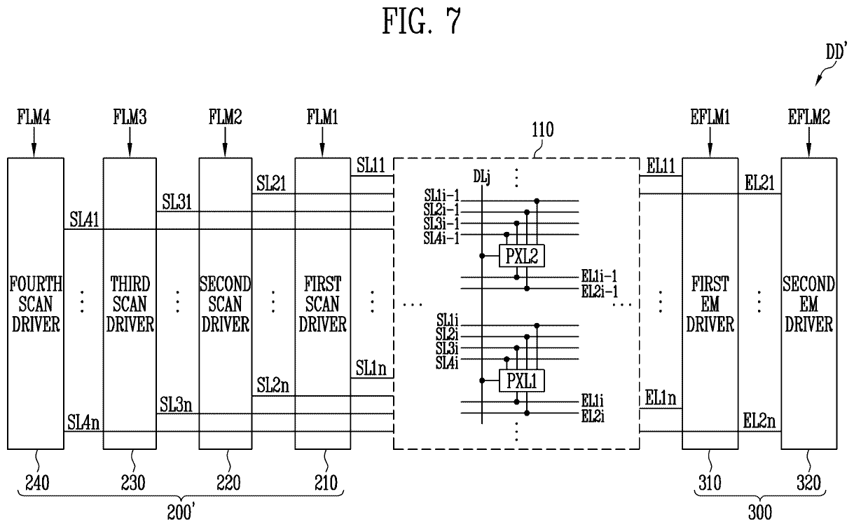

FIG. 7 is a block diagram illustrating another embodiment of a scan driver and an emission driver, which are shown in the display device of FIG. 1.

Referring to FIGS. 1 and 7, the scan driver 200′ may include a first scan driver 210, a second scan driver 220, a third scan driver 230, and a fourth scan driver 240.

The first to third scan drivers 210 to 230 of FIG. 7 may be configured in the same manner as the first to third scan drivers 210 to 230 in FIG. 2. Hereinafter, overlapping descriptions will be omitted.

In embodiments, the first pixel PXL1 disposed in the i-th (i is a natural number greater than 1) row and the j-th (j is a natural number) column may be connected to the fourth scan line SL4i corresponding to the fourth pixel row. The second pixel PXL2 disposed in the i-1th row and the j-th column may be connected to the 4-1th scan line SL4i-1 corresponding to the fourth pixel row.

The scan driver 200 may receive the scan control signal SCS from the timing controller 500 and apply the fourth scan lines S41 to S4n based on the scan control signal SCS.

The scan control signal SCS may further include a fourth scan start signal FLM4. The fourth scan start signal FLM4 may be applied to the fourth scan driver 240.

The width, application timing, and the like of the fourth scan start signals FLM4 may be determined according to driving conditions and frame frequencies of the pixels PXL. The first to fourth scan signals may be applied based on the first to fourth scan start signals FLM1 to FLM4, respectively. For example, the application timing of at least one of the first to fourth scan signals may be different from the application timing of the remaining signals.

The fourth scan driver 240 may sequentially apply the fourth scan signal to the fourth scan lines S41 to S4n in response to the fourth scan start signal FLM4.

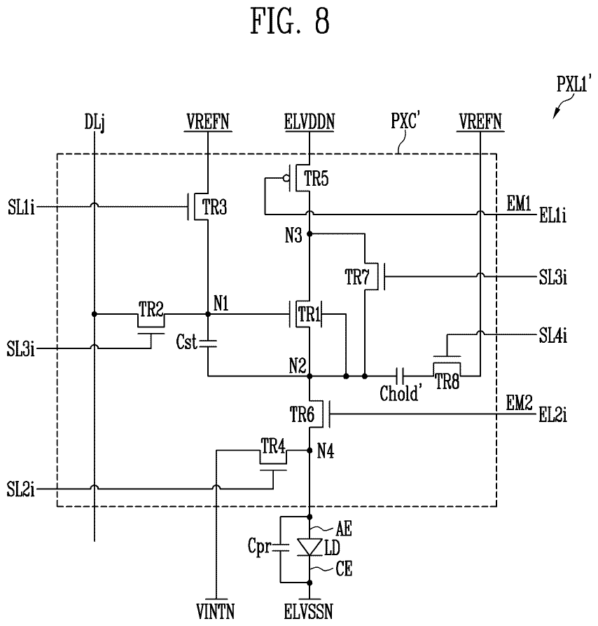

FIG. 8 is a circuit diagram illustrating another embodiment of any one of the pixels shown in FIG. 7.

Since the first pixel PXL1′ of FIG. 8 is the same as the configuration of the first pixel TXL1 described with reference to FIG. 3 except for the eighth transistor TR8 and the second capacitor Chold′, the same or corresponding components are denoted by the same reference numerals, and redundant descriptions are omitted.

Referring to FIG. 8, the first pixel PXL1′ may include a pixel circuit PXC′ and a light emitting element LD. The pixel circuit PXC′ may include first to eighth transistors TR1 to TR8, a first capacitor Cst, and a second capacitor Chold′.

The eighth transistor TR8 may be connected between the second node N2 and the reference power node VREFN. The gate electrode of the eighth transistor TR8 is connected to the fourth sub scan line SL4i, so that the eighth transistor TR8 may be turned on in response to the scan signal of the fourth sub scan line SL4i.

The second capacitor Chold′ may be connected between the eighth transistor TR8 and the second node N2. One electrode of the second capacitor Chold′ may be connected to the back gate electrode of the first transistor TR1. Another electrode of the second capacitor Chold′ may be connected to one electrode of the eighth transistor TR8. For example, when the eighth transistor TR8 is turned on, a voltage of the reference power node VREFN may be provided to another electrode of the second capacitor Chold′. The second capacitor Chold′ may store a voltage corresponding to the voltages of the second node N2 and the reference power node VREFN.

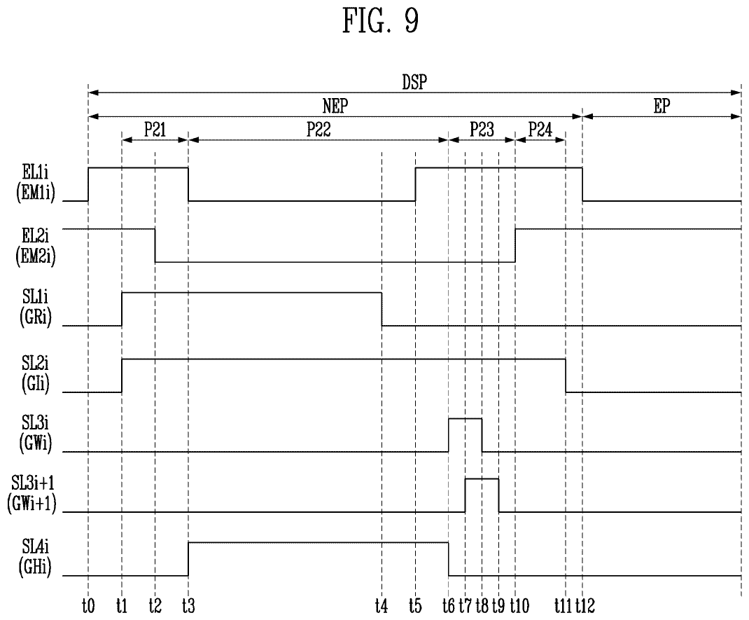

FIG. 9 is a timing diagram illustrating an embodiment of signals supplied to the pixel shown in FIG. 8.

Since the first pixel PXL1′ in FIG. 9 is the same as the operation of the first pixel TXL1 described with reference to FIG. 4 except for the fourth sub scan line SL4i connected to the gate electrode of the eighth transistor TR8, the same or corresponding operation will not be described repeatedly.

Referring to FIGS. 8 and 9, the display scan period DSP may include a non-emission period NEP and an emission period EP. The non-emission period NEP may include an initialization period P21, a threshold voltage compensation period P22, a data write period P23, and an anode initialization period P24.

The fourth scan signal GHi applied to the fourth sub scan line SL4i at the third time point t3 may transition from a logic low level to a logic high level. A fourth scan signal GHi of a logic high level at the third time point t3 may be provided to the gate electrode of the eighth transistor TR8. As the eighth transistor TR8 is turned on in response to the fourth scan signal GHi, a voltage of the reference power node VREFN may be provided to one electrode of the second capacitor Chold′.

The fourth scan signal GHi applied to the fourth sub scan line SL4i at the sixth time point t6 may transition from a logic high level to a logic low level. At a sixth time t6, the eighth transistor TR8 may be turned off.

Although FIG. 9 shows that the fourth scan signal GHi is applied from the third time point t3 to the sixth time point t6, the present disclosure is not limited thereto. The fourth scan signal GHi may be provided to the gate electrode of the eighth transistor TR8 between the time when the initialization period P21 ends and the time when the third scan signal GWi is applied. For example, the fourth scan signal GHi may be applied from the third time point t3 to the fifth time point t5.

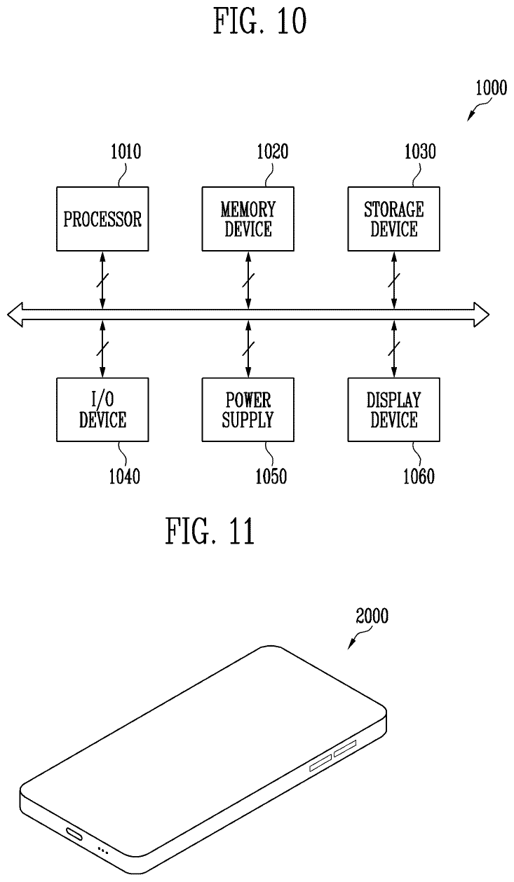

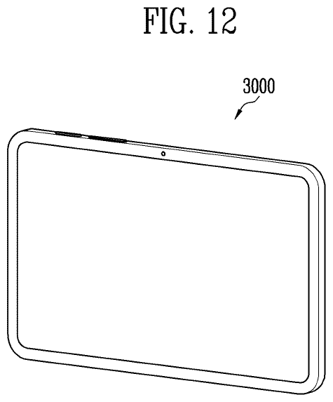

FIG. 10 is a block diagram illustrating an embodiment of an electronic device 1000 including the display device of FIG. 1. FIG. 11 is a diagram illustrating an example where the electronic device 1000 of FIG. 10 is a smartphone. FIG. 12 is a diagram illustrating an example where the electronic device 1000 of FIG. 10 is a tablet computer.

Referring to FIG. 10, the electronic device 1000 may include a processor 1010, a memory device 1020, a storage device 1030, an input/output device 1040, a power supply device 1050, and a display device 1060. The processor 1010 may be implemented as more than one processor.

In embodiments, as shown in FIG. 11, the electronic device 1000 may be implemented as a smartphone 2000. In other embodiments, as shown in FIG. 12, the electronic device 1000 may be implemented as a tablet computer 3000. However, this is exemplary, and the electronic device 1000 is not limited thereto. For example, the electronic device 1000 may be a computer device or an electronic device including the display device 1060, such as a digital television, a 3D TV, a personal computer (PC), a home electronic device, a laptop computer, a mobile phone, a video phone, a smart pad, a smart watch, a head mounted display device, a personal digital assistant (PDA), a portable multimedia player (PMP), a digital camera, a music player, a portable game console, navigation, and the like.

The processor 1010 may perform various tasks and calculations. In embodiments, the processor 1010 may include an application processor, a graphics processing unit, a microprocessor, a central processing unit (CPU), or the like. The processor 1010 may be connected to other components of the electronic device 1000 through a bus system. In embodiments, the bus system may include a Peripheral Component Interconnect (PCI) bus. The processor 1010 may provide a data stream to be displayed on the display device 1060 to the display device 1060. The data stream may be provided to the display device 1060 as the input image data IMG of FIG. 1. The processor 1010 may further transmit the control signal CTRL of FIG. 1 to the display device 1060.

The memory device 1020 may be provided as a working memory or a buffer memory of the electronic device 1000 or the processor 1010. In embodiments, memory device 1020 may include volatile memory devices such as dynamic random access memory (DRAM), static random access memory (SRAM), mobile DRAM, and the like.

The storage device 1030 may store data in response to control of the processor 1010. The storage device 1030 may include a nonvolatile storage medium that maintains data even when the power of the electronic device 1000 is cut off. In embodiments, storage device 1030 may include a Solid State Drive (SSD), a Hard Disk Drive (HDD), or the like.

The input/output device 1040 may include user input devices such as a keyboard, keypad, touchpad, touchscreen, mouse, and the like, and output devices such as a speaker, printer, and the like.

The power supply device 1050 may supply power required for the operation of the electronic device 1000. For example, the power supply 1050 may be a power management integrated circuit (PMIC). For example, the power supply 1050 may include a battery.

The display device 1060 may display an image in response to the control of the processor 1010. The display device 1060 may be connected to other components of the electronic device 1000 via a bus system or other communication link. The display device 1060 may be implemented as the display device DD of FIG. 1. An image may be displayed on pixels PX of the display device 1060, and each of the pixels PX may be configured as any one of pixels PXL1 and PXL1′ of FIGS. 3 and 8.

In the pixel according to the embodiments of the present disclosure and the display device including the same, the pixel combines N-type low-temperature polycrystalline silicon transistors and oxide semiconductor transistors to be used, thereby improving display quality of the display device. In addition, the stage circuit of the scan driver for driving a pixel combines and uses oxide semiconductor transistors based on N-type low-temperature polycrystalline silicon transistors, so that defects in the display panel such as flicker phenomenon may be suppressed while securing a fast driving speed.

According to embodiments of the present disclosure, a pixel, a display device, and an electronic device having improved display quality are provided.

The effects according to the embodiments are not limited by the content illustrated above, and more various effects are included in the present specification.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A pixel comprising:
a first transistor having a gate electrode connected to a first node, the first transistor being connected between a second node and a third node;
a second transistor connected between a data line and the first node, and having a gate electrode electrically connected to a third scan line;
a third transistor connected between a reference power node and the first node, and having a gate electrode electrically connected to a first scan line;
a fourth transistor connected between the initialization power node and a fourth node, and having a gate electrode electrically connected to a second scan line;
a fifth transistor connected between a first driving power node, to which a first driving power is supplied, and the third node, and having a gate electrode electrically connected to a first light emission control line;
a sixth transistor connected between the second node and the fourth node, and having a gate electrode electrically connected to a second light emission control line;
a seventh transistor connected between the second node and the third node, and having a gate electrode electrically connected to the third scan line; and
a light emitting element connected to the fourth node,
wherein, in operation, the seventh transistor is turned on in response to a scan signal applied to the third scan line electrically connecting the second node and the third node to each other.

2. The pixel according to claim 1, further comprising:
a first capacitor connected between the first node and the second node; and
a second capacitor connected between the first driving power node and the second node.

3. The pixel according to claim 2, wherein the first transistor further comprises a back gate electrode connected to one electrode of the second capacitor and the second node.

4. The pixel according to claim 1, wherein the light emitting element is connected between a second driving power node, to which a second driving power is supplied, and the fourth node.

5. The pixel according to claim 1, further comprising:
a first capacitor connected between the first node and the second node; and
a second capacitor connected between the reference power node and the second node.

6. The pixel according to claim 5, wherein the first transistor further comprises a back gate electrode connected to one electrode of the second capacitor and the second node.

7. The pixel according to claim 5, further comprising:
an eighth transistor connected between an electrode of the second capacitor and the reference power node, and having a gate electrode electrically connected to a fourth scan line.

8. The pixel according to claim 1, wherein, in a first period, the scan signal of the third scan line is supplied, and
wherein the first period includes a plurality of horizontal periods.

9. The pixel according to claim 8, wherein the first period includes a first sub-period and a second sub-period subsequent to the first sub-period, and wherein each of the first and second sub-periods includes at least one horizontal period.

10. The pixel according to claim 9, wherein, in the first sub-period, a previous data signal is applied to a gate electrode of the first transistor through the second transistor, and
wherein, in the second sub-period, a data signal corresponding to the pixel is applied to the gate electrode of the first transistor through the second sub-period.

11. The pixel according to claim 10, wherein, in the first sub-period, the second node is electrically connected to the third node through the seventh transistor, such that a voltage level of the second node is substantially the same as the voltage level of the third node.

12. The pixel according to claim 8, wherein, in the first period, the second and seventh transistors are turned on, and the third, fifth, and sixth transistors are turned off.

13. A display device comprising:
pixels connected to scan lines, light emission control lines, and data lines; and
a scan driver for driving the scan lines,
wherein any one of the pixels comprises:
a first transistor having a gate electrode connected to a first node, the first transistor being connected between a second node and a third node;
a second transistor connected between a data line and the first node, and having a gate electrode electrically connected to a third scan line of the scan lines;
a third transistor connected between a reference power node and the first node, and having a gate electrode electrically connected to a first scan line of the scan lines;
a fourth transistor connected between the initialization power node and a fourth node, and having a gate electrode electrically connected to a second scan line of the scan lines;
a fifth transistor connected between a first driving power node, to which a first driving power is supplied, and the third node, and having a gate electrode electrically connected to a first light emission control line of the light emission control lines;
a sixth transistor connected between the second node and the fourth node, and having a gate electrode electrically connected to a second light emission control line of the light emission control lines;
a seventh transistor connected between the second node and the third node, and having a gate electrode electrically connected to the third scan line; and
a light emitting element connected to the fourth node,
wherein, in operation, the seventh transistor is turned on in response to a scan signal applied to the third scan line electrically connecting the second node and the third node to each other.

14. The display device according to claim 13, further comprising:
a first capacitor connected between the first node and the second node; and
a second capacitor connected between the first driving power node and the second node.

15. The display device according to claim 13, further comprising:
a first capacitor connected between the first node and the second node;
a second capacitor connected between the reference power node and the second node; and
an eighth transistor connected between an electrode of the second capacitor and the reference power node, and having a gate electrode electrically connected to a fourth scan line of the scan lines.

16. The display device according to claim 13, wherein, in a first period, the scan signal of the third scan line is supplied, and
wherein the first period includes a plurality of horizontal periods.

17. The display device according to claim 16, wherein the first period includes a first sub-period and a second sub-period subsequent to the first sub-period, and wherein each of the first and second sub-periods includes at least one horizontal period.

18. The display device according to claim 17, wherein, in the first sub-period, a previous data signal is applied to a gate electrode of the first transistor through the second transistor, and
wherein, in the second sub-period, a data signal corresponding to the pixel is applied to the gate electrode of the first transistor through the second transistor.

19. The display device according to claim 18, wherein, in the first sub-period, the second node is electrically connected to the third node through the seventh transistor, such that a voltage level of the second node is substantially the same as the voltage level of the third node.

20. An electronic device comprising:
pixels; and
one or more processors configured to control the display device,
wherein any one of the pixels comprises:
a first transistor having a gate electrode connected to a first node, the first transistor being connected between a second node and a third node;
a second transistor connected between a data line and the first node, and having a gate electrode electrically connected to a third scan line;
a third transistor connected between a reference power node and the first node, and having a gate electrode electrically connected to a first scan line;
a fourth transistor connected between the initialization power node and a fourth node, and having a gate electrode electrically connected to a second scan line;
a fifth transistor connected between a first driving power supply node, to which a first driving power is supplied, and the third node, and having a gate electrode electrically connected to a first light emission control line;
a sixth transistor connected between the second node and the fourth node, and having a gate electrode electrically connected to a second light emission control line;
a seventh transistor connected between the second node and the third node, and having a gate electrode electrically connected to the third scan line; and
a light emitting element connected to the fourth node,
wherein, in operation, the seventh transistor is turned on in response to a scan signal applied to the third scan line electrically connecting the second node and the third node to each other.
